(19) United States
(12) Patent Application Publication
(10) Pub. No.: US 2008/0061898 A1
(43) Pub. Date: Mar. 13, 2008

(54) SC cut crystal unit and highly stable crystal oscillator

(75) Inventors: Tadayodshi Soga, Tokyo (JP); Tomohiro Moriguchi, Fukushima-shi (JP)

Correspondence Address: OLIFF & BERRIDGE, PLC, P.O. BOX 320850, ALEXANDRIA, VA, 22320-4850, US

(73) Assignee: EPSON TOYOCOM CORPORATION, TOKYO (JP)

(21) Appl. No.: 11/892,775

(22) Filed: Aug. 27, 2007

(30) Foreign Application Priority Data
Sep. 11, 2006 (JP) 2006-245156
Mar. 8, 2007 (JP) 2007-058174

(51) Int. Cl. H01L 41/18; H03B 5/32

(52) U.S. Cl. 331/158; 310/361

(57) ABSTRACT

An SC cut crystal unit includes an SC cut quartz substrate, an exciting electrode formed on each of both surfaces of the quartz substrate, a support member supporting each of two points of the quartz substrate, and a metal case sealing the quartz substrate therein. The support member supports each of two edge portions of the quartz substrate, the edge portion being on a line rotated 80 to 90 degrees from a line of a ZZ′ axis passing through a center axis of the quartz substrate.

### BACKGROUND

1. Technical Field

The present invention relates to an SC cut crystal unit which is particularly preferred for a quartz crystal device such as a surface-mounted highly stable crystal oscillator.

2. Related Art

It has been known an oven-controlled crystal oscillator (hereinafter, abbreviated to OCXO) as a highly stable crystal oscillator which is a frequency control device used for a mobile communication equipment and transmission communication equipment. The OCXO achieves greatly high frequency stability by mounting a crystal unit or a crystal unit and oscillation circuit in a thermostatic oven keeping a temperature stably.

In the related art, used in the above OCXO is an AT cut crystal unit. In recent years has been widely used a stress compensation (SC) cut crystal unit which has extremely small frequency variation at a relatively high temperature, or about 80 degrees centigrade.

An example of related art (listed below) discloses an SC cut crystal unit. In the SC cut crystal unit, resonance of an A mode and B mode can be suppressed to surely excite C mode resonance, and supported is an edge part on a surface of a plate of a quartz crystal element, with the plate being rotated 30 to 50 degrees from a Z axis direction.

Japanese Utility Model No. 2531304 is an example of related art.

In recent years, required also to the above OCXO has been a surface-mounted one which can be mounted on a printed-circuit board in the equipment, and has been developed. In a case the OCXO is mounted on the printed-circuit board in the equipment by a reflow process, oscillation frequency disadvantageously varies considerably. Further, there has been a problem the OCXO is not good in so-called rising characteristics after power-on until the oscillation frequency of the OCXO converges to a predetermined frequency to become stable.

As a result of studies by the present inventor in order to solve these problems, it is found that such failures described above occur due to characteristic change of the SC cut crystal unit used for the quartz crystal device such as the OCXO.

### SUMMARY

An advantage of the present invention is to provide an SC cut crystal unit which can suppress variation of oscillation frequency after the reflow process, and an SC cut crystal unit which is excellent in the rising characteristics of frequency after power-on.

According to a first aspect of the invention, an SC cut crystal unit includes an SC cut quartz substrate, an exciting electrode formed on each of both surfaces of the quartz substrate, a support member supporting each of two points of the quartz substrate, and a metal case sealing the quartz substrate therein. The support member supports each of two edge portions of the quartz substrate, the edge portion being on a line rotated 80 to 90 degrees from a line of a ZZ′ axis passing through a center axis of the quartz substrate. In this case, the frequency variation generated after the reflow process may be restrained and the rising characteristics of frequency after power-on may be improved.

According to a second aspect of the invention, an SC cut crystal unit includes an SC cut quartz substrate, an exciting electrode formed on each of both surfaces of the quartz substrate, a support member supporting each of two points of the quartz substrate, and a metal case sealing the quartz substrate therein. The support member supports each of two edge portions of the quartz substrate, the edge portion being on a line rotated 165 to 180 degrees from a line of a ZZ′ axis passing through a center axis of the quartz substrate. In this case, the frequency variation generated after the reflow process may be restrained and the rising characteristics of frequency after power-on may be improved.

According to a third aspect of the invention, an SC cut crystal unit includes an SC cut quartz substrate, an exciting electrode formed on each of both surfaces of the quartz substrate, a support member supporting each of two points of the quartz substrate, and a metal case sealing the quartz substrate therein. The support member supports each of two edge portions of the quartz substrate, the edge portion being on a line rotated 140 to 150 degrees from a line of a ZZ′ axis passing through a center axis of the quartz substrate. In this case, the frequency variation generated after the reflow process may be restrained.

According to a fourth aspect of the invention, an SC cut crystal unit includes an SC cut quartz substrate, an exciting electrode formed on each of both surfaces of the quartz substrate, a support member supporting each of two points of the quartz substrate, and a metal case sealing the quartz substrate therein. The support member supports each of two edge portions of the quartz substrate, the edge portion being on a line rotated 0 to 5 degrees from a line of a ZZ′ axis passing through a center axis of the quartz substrate. In this case, the frequency variation generated after the reflow process may be restrained.

According to a fifth aspect of the invention, a highly stable crystal oscillator of includes the SC cut crystal unit of the above aspects of the invention. In this case, the highly stable crystal oscillator provided with the SC cut crystal unit of the aspects of the invention may have small variation of oscillation frequency due to the reflow process and be excellent in the rising characteristics of frequency after power-on until the oscillation frequency converges to a predetermined frequency to become stable.

### BRIEF DESCRIPTION OF THE DRAWINGS

The invention will be described with reference to the accompanying drawings, wherein like numbers reference like elements.

FIGS. 1(A), 1(B) and 1(C) show schematic configurations of an SC cut crystal unit according to an embodiment of the invention.

FIG. 1(A) is a perspective view showing a whole configuration of the crystal unit.

FIG. 1(B) is a front longitudinal sectional view of the crystal unit.

FIG. 1(C) is a side longitudinal sectional view of the crystal unit.

FIGS. 2(A), 2(B) and 2(C) show a support mechanism for a quartz substrate in the crystal unit according to the embodiment.

FIG. 3 is a graph showing frequency variation characteristics of the SC cut crystal unit after a reflow process.

FIG. 4 a graph showing rising characteristics of the SC cut crystal unit.

FIGS. 5(A) and 5(B) are graphs showing the rising characteristics of the cut crystal unit.

FIGS. 6(A) and 6(B) are graphs showing the rising characteristics of the cut crystal unit.

FIG. 7 is a graph showing frequency reproducibility of the SC cut crystal unit after being left at a low temperature.

FIG. 8 is a graph showing a result of G-sens for the SC cut crystal unit.

FIG. 9 is a graph showing an analysis result for the SC cut crystal unit by a finite element method (FEM).

FIG. 10 shows another configuration of the electrode in the crystal unit according to the embodiment.

FIG. 11 shows a configuration example of a highly stable crystal oscillator provided with the SC cut crystal unit according to the embodiment of the invention.

### DESCRIPTION OF EXEMPLARY EMBODIMENTS

Here, embodiments to the invention will be described in detail with reference to the drawings.

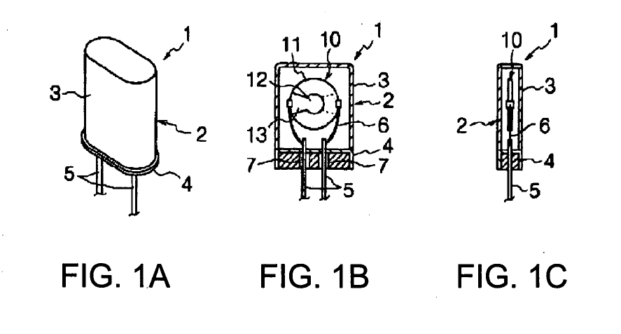

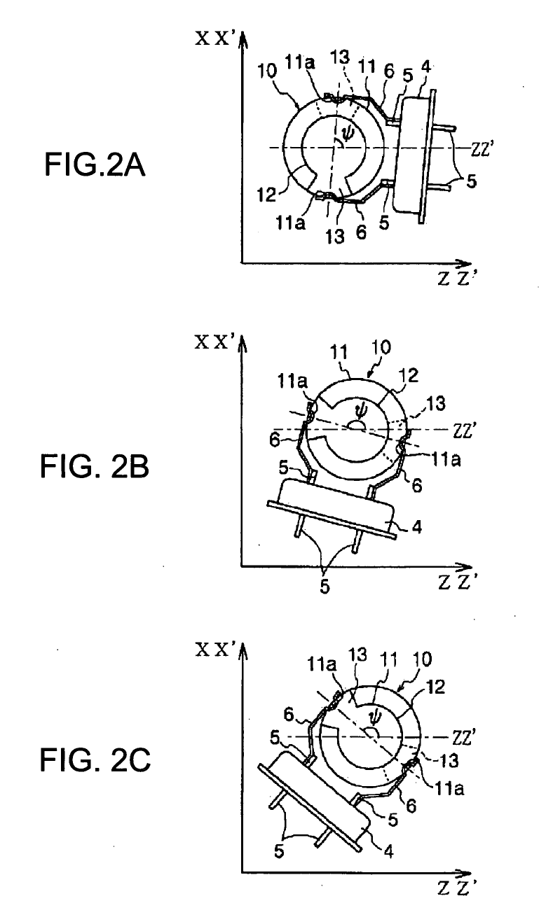

FIGS. 1(A), 1(B) and 1(C) show schematic configurations of an SC cut crystal unit according to an embodiment of the invention. FIG. 1(A) is a perspective view showing a whole configuration. FIG. 1(B) is a front longitudinal sectional view. FIG. 1(C) is a side longitudinal sectional view. FIGS. 2(A), 2(B) and 2(C) show a support mechanism for a quartz substrate in the crystal unit according to the embodiment.

Referring to FIGS. 1(A) to 1(C), the SC cut crystal unit 1 includes a crystal unit body 2 which is formed of a metal case 3 and a quartz resonator element 10 sealed in the metal case 3, and two lead terminals 5 projecting from the metal case 3 at a bottom 4 thereof. The quartz resonator element 10 includes an SC cut quartz substrate (quartz crystal element) 11 provided with a resonating part at a center thereof, an exciting electrode 12 formed on each of both surfaces of the quartz substrate 11, and two support members 6 supporting respectively two edges of the quartz substrate 11. Each of the support members 6 is coupled at one end thereof to a lead pattern 13 which is extracted from the exciting electrode 12 toward each of the opposite edges of the quartz substrate 11. The support member 6 is coupled at the other end thereof to each of the lead terminals 5 provided to the bottom 4.

The SC cut quartz substrate 11 of the embodiment is obtained by cutting out a quartz crystal in a state where a plane of the quartz crystal is rotated approximately 34 degrees from an optical axis (Z axis) direction, for example, 34 degrees 04′ 30″±30″, and approximately 22 degrees from an electrical axis (X axis) direction, for example, 22 degrees 20′±10′.

In the embodiment, referring to FIG. 2(A), the support member 6 supports each of two edge portions 11a of the quartz substrate 11, the edge portions 11a being on a line rotated 80 to 90 degrees from a line of a ZZ′ axis passing through a center axis of the quartz substrate 11 (or the optical axis passing through the center axis of the quartz substrate 11), for example. That is, an angle is defined by the ZZ′ axis passing through the center axis of the quartz substrate 11 and a line passing through the edge portions 11a supported by the two support members 6. The angle is referred to a support angle ψ by which the support members 6 support the quartz substrate 11 and is set about 80 to 90 degrees.

In the embodiment, referring to FIG. 2(B), the support member 6 supports each of two edge portions 11a of the quartz substrate 11, the edge portions 11a being on a line rotated 165 to 180 degrees from the line of the ZZ′ axis passing through the center axis of the quartz substrate 11, for example. That is, the support angle ψ is defined by the ZZ′ axis passing through the center axis of the quartz substrate 11 and the line passing through the edge portions 11a supported by the two support members 6. The angle ψ is set approximately 165 to 180 degrees.

It is found that, from the results of a test conducted by the present inventor, referring to FIGS. 2(A) and 2(B), if the support angle ψ with which the support member 6 supports the quartz substrate 11 is set 80 to 90 degrees or 165 to 180 degrees, frequency variation of the SC cut crystal unit 1 after the reflow process can be suppressed. It is also found that rising characteristics of frequency at power-on is good.

It is found that, referring to FIG. 2(C), in a case that the support angle ψ with which the support member 6 supports the quartz substrate 11 is set 140 to 150 degrees, the frequency variation after the reflow process can be suppressed. Further, it is found that in a case that the support angle ψ with which the support member 6 supports the quartz substrate 11 is set 0 to 5 degrees, the rising characteristics of frequency at power-on is good.

Hereinafter, the characteristic test of the SC cut crystal unit conducted by the inventor will be described.

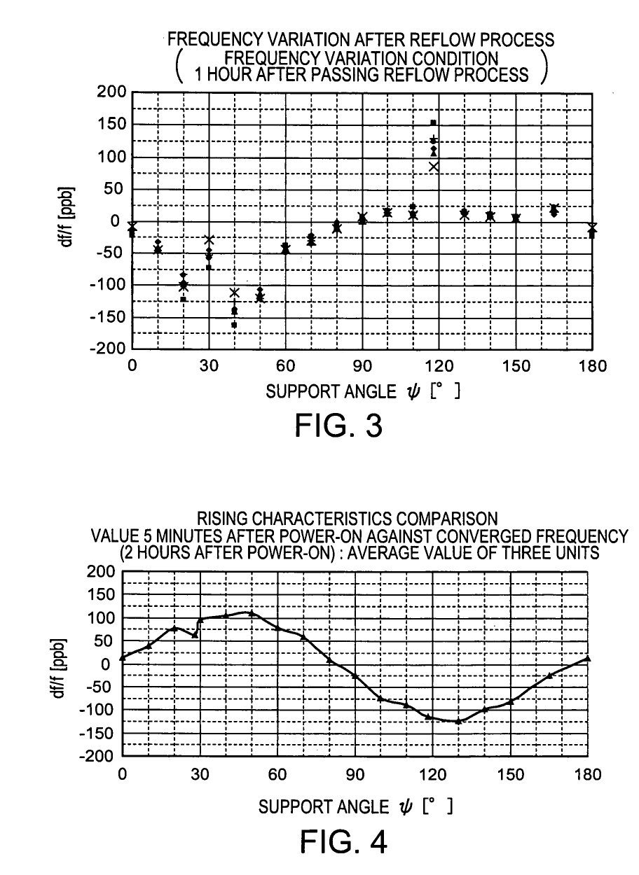

FIG. 3 shows a relationship between the support angle for the quartz substrate in the SC cut crystal unit and the frequency variation after the reflow process. Referring to FIG. 3, frequency variation df/f is found by frequency f (ambient temperature Ta=+80 degrees C., transmission method) measured in one unit of the SC cut crystal unit 1 and frequency df 1 hour after passing the reflow process (peak temperature, approximately 220 degrees C.). It is preferable the frequency variation df/f is small. Here, the frequency variation df/f within ±25 ppb is regarded as preferable.

It is found that, as the results of the test shown in FIG. 3, the frequency variation is large with the support angle ψ in a range of 10 to 60 degrees and in a vicinity of 120 degrees, but it is desirable except in that temperature range. It is found that the frequency variation after the reflow process can be restrained particularly by setting the support angle ψ in a range of 80 to 90, 140 to 150, or 165 to 180 degrees.

Next, FIG. 4 shows a relationship between the support angle for the quartz substrate in the SC cut crystal unit and the rising characteristics of frequency at power-on. Referring to FIG. 4, the rising characteristics is measured using an OCXO configured by the SC cut crystal unit 1 shown in FIGS. 1(A) to 1(C) as a measured object. At this time, oven temperatures for the measured object are set to be substantially identical. The rising characteristics are determined by comparing reference frequency f with the frequency df 5 minutes after power-on with the ambient temperature Ta=25±1 degrees C. The reference frequency f at this time is set to be a frequency 2 hours after power-on. It is preferable the frequency variation df/f is small. The frequency variation df/f within ±25 ppb is also regarded as preferable (stable).

It is found that, as the results of the test shown in FIG. 4, the frequency becomes stable a short time (5 minutes) after power-on in a case that the support angle ψ for the quartz substrate 11 is set in a range of 80 to 90, or 165 to 180 degrees.

Therefore, it is found that, as the results of the test shown in FIG. 3 and FIG. 4, if the support angle ψ for the quartz substrate 11 is set in the range of 80 to 90, or 165 to 180 degrees, the frequency variation after the reflow process can be suppressed and the rising characteristics of frequency after power-on can be improved.

Moreover, the inventor studied in detail the rising characteristic of the cut crystal unit for each support angle.

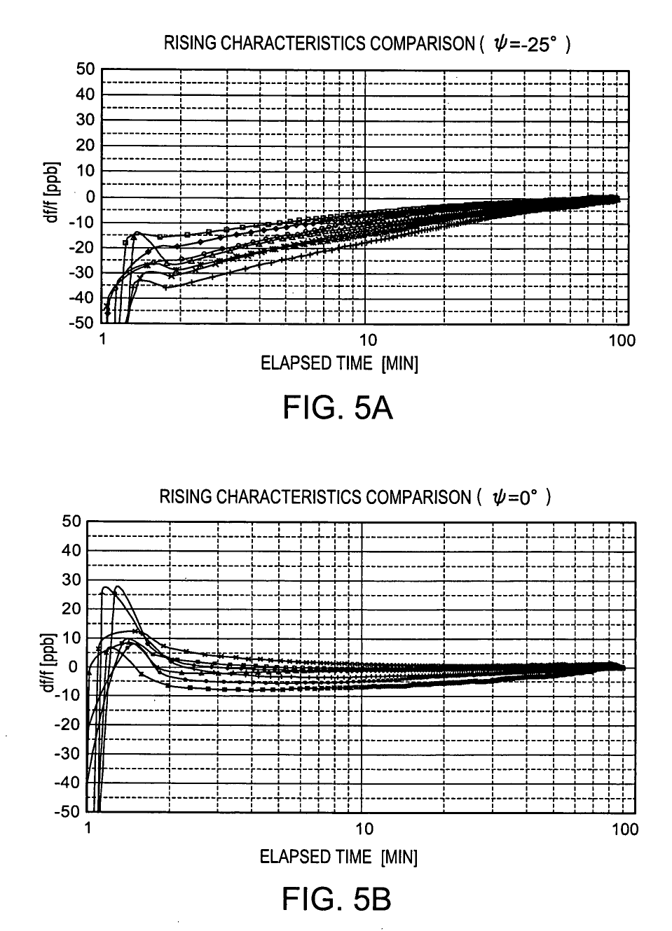

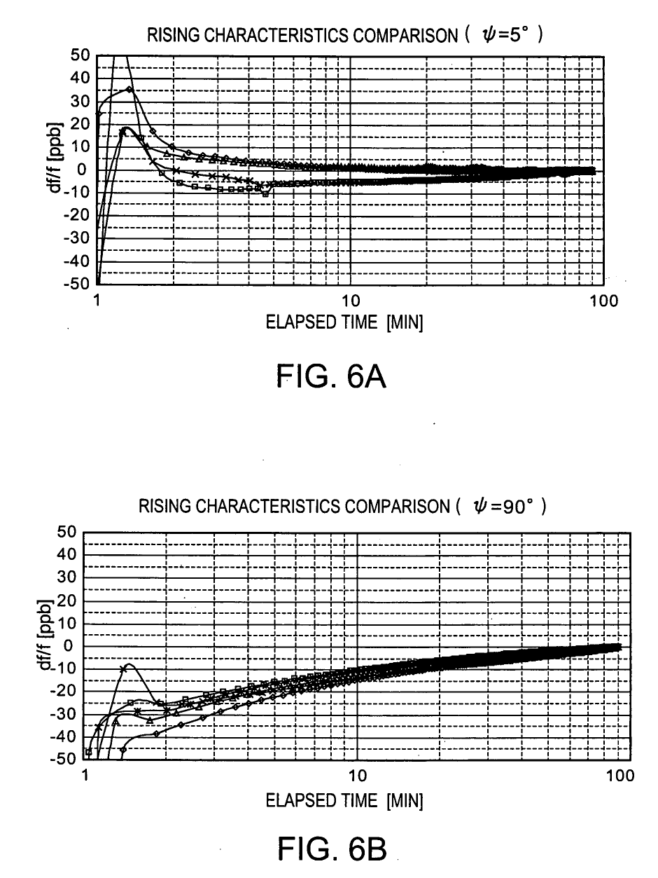

FIGS. 5(A) and 5(B), and FIGS. 6(A) and 6(B) show the rising characteristics of the SC cut crystal unit for each support angle. Referring to FIGS. 5(A) and 5(B), and FIGS. 6(A) and 6(B), the rising characteristics is measured using an OCXO configured by the SC cut crystal unit 1 shown in FIGS. 1(A) to 1(C) as a measured object. At this time, oven temperatures for the measured object are set to be substantially identical. The reference frequency f is set to a frequency 90 minutes after power-on, and the frequency df is set to a frequency at a time elapsed from rising with the ambient temperature Ta=25±1 degrees C. The rising characteristics are determined by comparing the reference frequency f with the frequency df. FIGS. 5(A) and 5(B) show rising characteristics comparison of the quartz substrate for the support angles ψ of −25 (=155) degrees and 0 degree, respectively. FIGS. 6(A) and 6(B) show rising characteristics comparison of the quartz substrate for the support angles ψ of 5 and 90 degrees, respectively.

Referring to FIG. 5(A), in the case of the support angle ψ for the quartz substrate 11 of −25 (=155) degrees, the frequency variation (df/f) 5 minutes after power-on has deviation as large as −10 to −30 ppb, and the frequency is not stable. The frequency is found to be in an unsteady state.

Referring to FIG. 5(B), in the case of the support angle ψ for the quartz substrate 11 of 0 degree, the frequency variation (df/f) 5 minutes after power-on has deviation as small as +5 to −10 ppb. The frequency is found to be stable.

Referring to FIG. 6(A), in the case of the support angle ψ for the quartz substrate 11 of +5 degrees, the frequency variation (df/f) 5 minutes after power-on has deviation as small as +5 to −10 ppb. The frequency is found to be stable.

Referring to FIG. 6(B), in the case of the support angle ψ for the quartz substrate 11 of 90 degrees, the frequency variation (df/f) 5 minutes after power-on has deviation as large as −15 to −25 ppb, and the frequency is not stable. The frequency is found to be in an unsteady state. These mean that the frequency is unstable for 90 minutes after power-on. However, as the results shown in FIG. 4, the frequency is significantly stable 2 hours after power-on. Therefore, it is found there is no problem unless performance of the SC cut crystal unit is required so strictly.

The result of the rising characteristics comparison shown in FIGS. 5(A) and 5(B), and FIGS. 6(A) and 6(B) indicates a similar tendency to that in FIG. 4. Therefore, it is confirmed the result of the rising characteristics comparison shown in FIG. 4 is correct.

The following is also found from the result of the rising characteristics comparison shown in FIGS. 5(A) and 5(B), and FIGS. 6(A) and 6(B). That is, in a case that the support angle ψ for the quartz substrate 11 is set to 0 or 5 degrees, the frequency variation (df/f) 5 minutes after power-on has deviation as small as within approximately ±10 ppb, and the frequency is stable. Therefore, the rising characteristics of frequency after power-on is extremely well also in the case of the support angle ψ for the quartz substrate 11 in a range of 0 to 5 degrees. Specifically, the support angle ψ is optimally set in the range of 0 to 5 degrees if performance for the rising characteristics is required particularly strictly for 90 minutes after power-on.

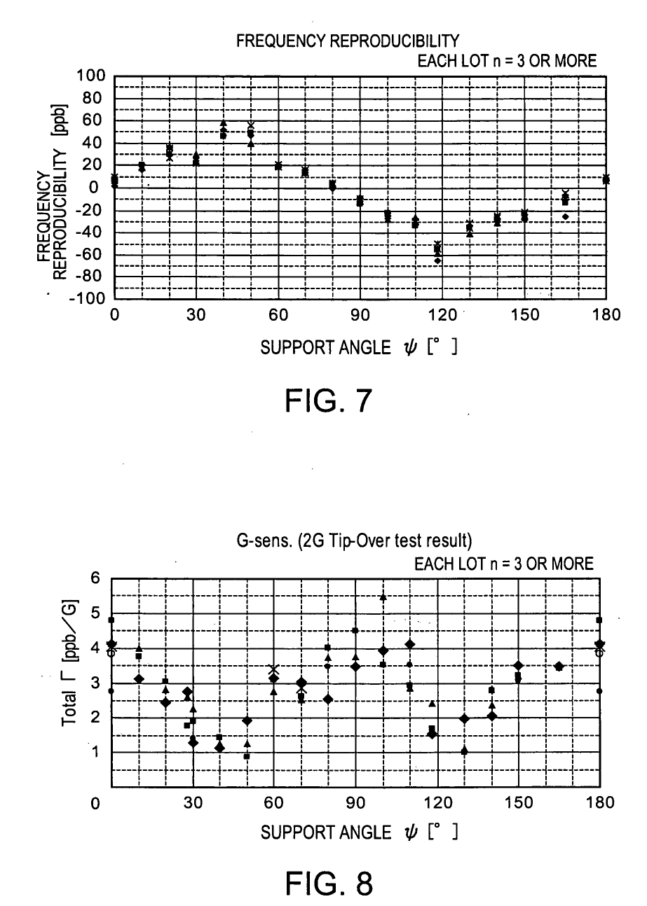

The inventor conducted various characteristic tests in addition to that of the relationship between the support angle and the frequency variation characteristics after the reflow process of the SC cut crystal unit as well as the relationship between the support angle and the rising characteristics described above. The results of the tests are shown in FIG. 7 to FIG. 11.

FIG. 7 shows a relationship between the support angle for the quartz substrate of the SC cut crystal unit and frequency reproducibility thereof after being left at a low temperature. In the characteristic test shown in FIG. 7, the frequency reproducibility is found as follows. The reference frequency is set to a frequency of the unit which is energized for 24 hours or more. After measuring the reference frequency, the unit is left power-off for 24 hours. Next, the unit again is energized for 24 hours, and the frequency is measured and then compared with the reference frequency.

Referring to FIG. 7, the frequency reproducibility is found to be good in a case that the support angle ψ for the quartz substrate 11 is set in the vicinity of a range of 80 to 90, or 165 to 180 degrees.

FIG. 8 shows a relationship between the support angle for the quartz substrate and G-sens. Referring to FIG. 8, G-sens characteristics is fine by setting the support angle ψ for the quartz substrate 11 to in the vicinity of 40 or 130 degrees.

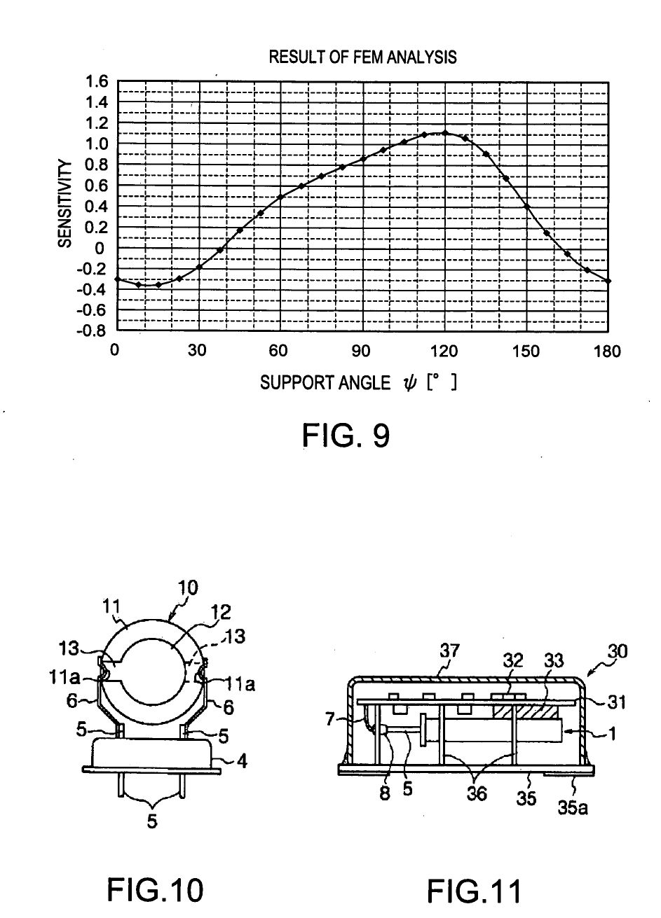

FIG. 9 shows a result of study on an optimum support angle by a finite element method (FEM) analysis. From the result, the optimum support angle ψ is found to be in the vicinity of 40 or 165 degrees.

The test results described above leads to the following conclusion. It has been considered in the related art, the optimum support angle ψ, such as about 40 or 165 degrees, to be the strongest to bear stress and most suitable to hold the quartz substrate 11. However, from the results of FEM analysis shown in FIG. 9, the optimum support angle is different depending on required characteristics. Concretely, with regard to the whole characteristics in the SC cut crystal unit, setting the optimum support angle ψ to 80 to 90 (preferably in the vicinity of 85) degrees, 165 to 180 degrees, or 0 to 5 degrees enables the frequency variation generated after the reflow process to be restrained and the good rising characteristics of frequency after power-on.

Incidentally, in the SC cut crystal unit of the above-described embodiment, the lead pattern 13 is formed so as to extend from the exciting electrode 12, provided on each of both surfaces of the quartz substrate 11, toward the edge of the quartz substrate 11. Here, referring back to FIG. 1(B), a pattern width of the lead pattern 13 is made wider on the side of the edge of the quartz substrate 11 than on the side of the exciting electrode 12, in order to secure the coupling with the support member 6. This likely causes variations in the support angle ψ with which the support member 6 supports the quartz substrate 11 when coupling the support member 6 to the lead pattern 13 of the quartz substrate 11.

Referring to FIG. 10, in the SC cut crystal unit according to another embodiment, the pattern width of the lead pattern 13 formed so as to extend from the exciting electrode 12 of the quartz substrate 11 toward the edge of the quartz substrate 11 is made narrower on the side of the edge than that of the quartz substrate 11 shown in FIG. 1(B). Specifically, the pattern width of the lead pattern 13 on the side of the exciting electrode 12 is made substantially the same as that on the side of edge of the quartz substrate 11. This configuration enables suppressing the variations in the support angle ψ generated when coupling the support member 6 with the lead pattern 13 of the quartz substrate 11. Therefore, accuracy of the support angle ψ can be improved. With this configuration, the more accurately the support angle ψ is set on coupling the support member, the more reliably the frequency variation can be prevented from occurring after the reflow process. Further, the rising characteristics frequency after power-on can be improved.

In the embodiment, the quartz substrate 11 included in the crystal unit 1 has a disk shape, but is not limited thereto. The quartz substrate 11 may have a strip shape.

The embodiment exemplifies the crystal unit having the lead terminal, but is obviously applicable to a surface-mounted crystal unit not having the lead terminal.

FIG. 11 shows a configuration example of a highly stable crystal oscillator provided with the SC cut crystal unit according to the embodiment of the invention.

The highly stable crystal oscillator 30 includes the SC cut crystal unit 1, a printed-circuit board 31, circuit components 32, a mother printed-circuit board 35 and a metal oscillator case 37. The printed-circuit board 31 supports on a surface thereof the crystal unit body 2 (the metal case 3) of the SC cut crystal unit 1, and couples a wiring pattern thereof with the lead terminal 5 of the SC cut crystal unit 1. The circuit components 32 are mounted on the printed-circuit board 31 and include oscillation circuit components and temperature compensation circuit components disposed so as to be in contact with a surface of the crystal unit body 2. The mother printed-circuit board 35 supports the printed-circuit board 31 with a heater resistance (power transistor, etc.) 33 and a pin 36 therebetween, and is provided on the bottom thereof with a mount terminal 35a to be surface-mounted. The metal oscillator case 37 surrounds the printed-circuit board 31 and a space including various components mounted on the printed-circuit board 31. Here, constructed by the crystal unit 1, the printed-circuit board 31, the heater resistance 33 and the circuit component 32 is a crystal oscillator heater unit (heater unit piezoelectric oscillator).

The crystal unit 1 is mounted as follows. An end of the lead terminal 5 is coupled to an end of a conductive connecting member 7 extending toward the surface of the printed-circuit board 31. On the surface of the printed-circuit board, the other end of the conductive connecting member 7 is coupled to a wiring pattern on the board by soldering.

In a case the SC cut crystal unit 1 is mounted to such a highly stable crystal oscillator 30, the crystal oscillator 30 has small variation of oscillation frequency due to the reflow process and is excellent in the rising characteristics of frequency after power-on until the oscillation frequency converges to a predetermined frequency to become stable.

The embodiment exemplifies the highly stable crystal oscillator as an example of the quartz crystal device provided with the SC cut crystal unit according to the embodiment of the invention. The SC cut crystal unit according to the embodiment of the invention may be applied to other quartz crystal devices than the highly stable crystal oscillator, and particularly preferably applied to a surface-mounted quartz crystal device.

What is claimed is:

1. An SC cut crystal unit comprising:
an SC cut quartz substrate;
an exciting electrode formed on each of both surfaces of the quartz substrate;
a support member supporting each of two points of the quartz substrate; and
a metal case sealing the quartz substrate therein, wherein
the support member supports each of two edge portions of the quartz substrate, the edge portion being on a line rotated 80 to 90 degrees from a line of a ZZ′ axis passing through a center axis of the quartz substrate.

2. An SC cut crystal unit comprising:
an SC cut quartz substrate;
an exciting electrode formed on each of both surfaces of the quartz substrate;
a support member supporting each of two points of the quartz substrate; and
a metal case sealing the quartz substrate therein, wherein
the support member supports each of two edge portions of the quartz substrate, the edge portion being on a line rotated 165 to 180 degrees from a line of a ZZ′ axis passing through a center axis of the quartz substrate.

3. An SC cut crystal unit comprising:
an SC cut quartz substrate;
an exciting electrode formed on each of both surfaces of the quartz substrate;
a support member supporting each of two points of the quartz substrate; and
a metal case sealing the quartz substrate therein, wherein
the support member supports each of two edge portions of the quartz substrate, the edge portion being on a line rotated 140 to 150 degrees from a line of a ZZ′ axis passing through a center axis of the quartz substrate.

4. An SC cut crystal unit comprising:
an SC cut quartz substrate;
an exciting electrode formed on each of both surfaces of the quartz substrate;
a support member supporting each of two points of the quartz substrate; and
a metal case sealing the quartz substrate therein, wherein
the support member supports each of two edge portions of the quartz substrate, the edge portion being on a line rotated 0 to 5 degrees from a line of a ZZ′ axis passing through a center axis of the quartz substrate.

5. A highly stable crystal oscillator comprising an SC cut crystal unit according to claims 1.
